(19) United States
(12) Patent Application Publication
(10) Pub. No.: US 2003/0057540 A1
(43) Pub. Date: Mar. 27, 2003

(54) Combination-type 3D stacked IC package

(76) Inventor: Wen-Lo Shieh, Taipei (TW)

Correspondence Address: Wen Lo Shieh, PO Box 82-144, Taipei, TW

(21) Appl. No.: 10/161,744

(22) Filed: Jun. 5, 2002

(30) Foreign Application Priority Data
Sep. 26, 2001 (TW) 090123853

(51) Int. Cl. H01L 23/02

(52) U.S. Cl. 257/686

(57) ABSTRACT

A method type 3D stacked IC package is disclosed. The present invention has an appropriate chip interposer (organic substrate, soft PI substrate) which is connected to the chip by flip chip method or wire bonding method. Another similar interposer and the connected chip are formed between the top face of the original interposer and the two interposers, and anisotropic conductive film/paste is employed to connect a flexible circuit board to between the first interposer and the inner side of the second interposer to form a 3-D structure. The top face of the interposer is connected to a chip to form an extended structure. Additionally, the top layer is formed as a bottom layer to provide with one or more than one similar extended structure.

### BACKGROUND OF THE INVENTION

(a) Field of the Invention

The present invention relates to semiconductor packaging technology, and in particular, to a combination-type 3D stacked IC package, allowing flexible number of stacked layers formed as an IC package.

(b) Description of the Prior Art

In semiconductor device, in order to increase the integration of the device, one of the method is to re-design the specification of the chip so as to upgrade the 1/0 pins, and another common method is by stacking two chips on an interposer, as shown in FIG. 1. An interposer 3′ having mounted with solder ball 4′ makes used of metallic wire 12′ to connect electrically chip paste 13′ onto a first chip 1′. Next, the chip paste 13′ on the first chip 1′ is adhered to a second chip 2′. The pin 21′ of the second chip 2′ is electrically connected to the interposed 3′ with metallic wire 22′. Another conventional stacked chip package structure is shown in FIG. 2, the interposer 3′ with protrusion 4′ at the bottom face is connected electrically by flip chip method. Next, the chip paste 23′ on the first chip 1′ is used to adhered a second chip 2′, and the pin 21′ of the second chip 2′ is electrically connected to the interposer 3′ with the metallic wire 22′.

The above conventional structure may increase the density but due to the restriction of the structural design, the layer of the structure cannot be stacked.

### SUMMARY OF THE INVENTION

Accordingly, it is an object of the present invention to provide a combination-type 3D stacked IC package, wherein the high of layers of the packaging can be increased and maintained its reliability at the same time.

One aspect of the present invention is to provide a structure of a combination-type 3-D stack IC package comprising a first interposer mounted electrically with a first chip; a second interposer having electrically mounted with a second chip at the bottom face of the interposer; and a flexible circuit board at the inner side of the first interposer and the second interposer being anisotropic conductive film/paste connected to form a basic structure.

The foregoing object and summary provide only a brief introduction to the present invention. To fully appreciate these and other objects of the present invention as well as the invention itself, all of which will become apparent to those skilled in the art, the following detailed description of the invention and the claims should be read in conjunction with the accompanying drawings. Throughout the specification and drawings identical reference numerals refer to identical or similar parts.

Many other advantages and features of the present invention will become manifest to those versed in the art upon making reference to the detailed description and the accompanying sheets of drawings in which a preferred structural embodiment incorporating the principles of the present invention is shown by way of illustrative example.

### BRIEF DESCRIPTION OF THE DRAWINGS

FIG. 1 is a schematic view of a conventional 2-D stacked IC package.

FIG. 2 is a schematic view of another conventional 2-D stacked IC package.

FIG. 3A is a schematic view of the flip-chip chip-connection type basic structure of the present invention.

FIG. 3B is a schematic view of the first extension structure of the flip-chip chip-connection type of the present invention.

FIG. 3C is a schematic view of the second extension structure of the flip-chip chip-connection type of the present invention.

FIG. 4A is a schematic view of the bond-wiring chip connection type basic structure of the present invention.

FIG. 4B is a schematic view of the first extension structure of the bond-wiring chip connection of the present invention.

FIG. 4C is a schematic view of the second extension structure of the bond-wiring chip connection of the present invention.

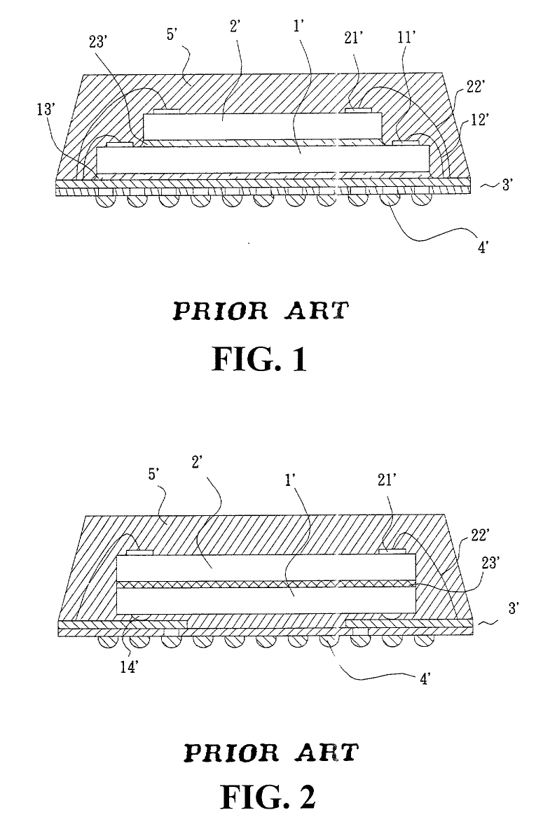

### DETAILED DESCRIPTION OF THE PRESENT INVENTION

For the purpose of promoting an understanding of the principles of the invention, reference will now be made to the embodiment illustrated in the drawings. Specific language will be used to describe same. It will, nevertheless, be understood that no limitation of the scope of the invention is hereby intended, alterations and further modifications in the illustrated device, and further applications of the principles of the invention as illustrated herein being contemplated as would normally occur to one skilled in the art to which the invention relates.

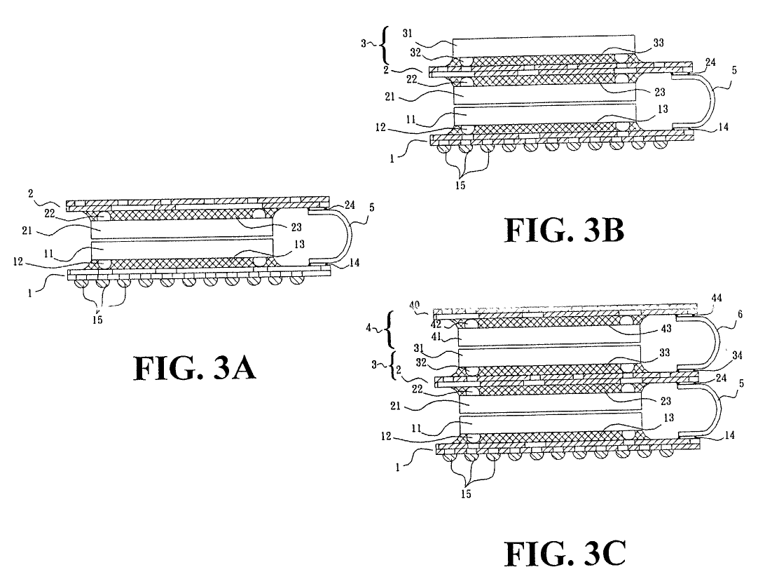

As shown in FIG. 3A, there is shown a first mode of molded 3D stacked IC package comprising:

(a) a first interposer 1 mounted electrically with a first chip 11; and the bottom face of the first interposer 1 is provided with solder ball 15;

(b) a second interposer 2 having electrically mounted with a second chip 21 at the bottom face of the interposer; and

(c) a flexible circuit board 5 at the first interposer 1 and the inner side of the second interposer 2 being anisotropic conductive film/paste 14, 24 connected to form a basic structure.

Referring to FIG. 3B, the top face of the second interposer 2 is added with a third chip 31 to form a first extended structure 3, wherein the top face of the second interposer 2 is acted as an interposer and a third chip 31 is provided to the interposer to perform a flip chip connection electrically.

Referring to FIG. 3C, the first extended structure of FIG. 3B is mounted with a third interposer 40, and a forth chip 41 is mounted to the bottom side of the interposer to connect with the third interposer 40. After that, a second flexible circuit board 6 at the second interposer 2 employs anisotropic conductive film/paste 34, 44 method to connect with the inner side of the third interposer 40 to form a second extended structure 4.

The above second extended structure 4 does not restrict to only two-layered structure, but under available space, multiple-layered structure can be formed. The first extended structure 3 can also be implemented on the second extended structure 4.

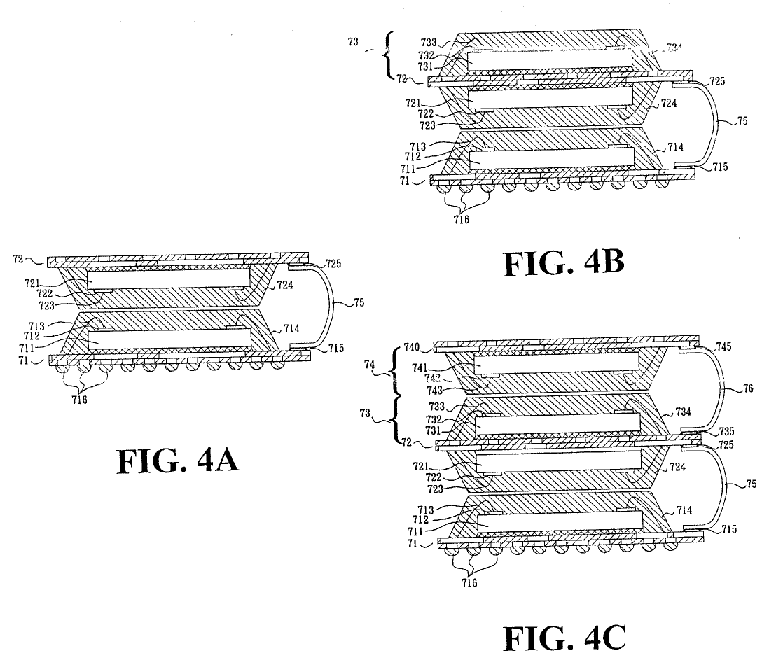

FIG. 4A is another preferred embodiment of the present invention. There is shown a second mode of combination-type 3D stacked IC package, wherein the package comprises a first interposer 71, having a solder ball 716 located at the first interposer 71, and the front face of the first interposer 71 is provided with a first chip 711 such that the first chip 711 and the interposer are wire bonded electrically. Furthermore, a second interposer 72 is provided, and a second chip 721 is mounted at the bottom face of the interposer such that the second chip 721 and the interposer are electrically wire bonded. Further a first flexible circuit board 75 on the first interposer 71 employs an anisotropic conductive film/paste 715, 725 method to connect the flexible circuit board 75 to the inner side of the second interposer 71 to form a basic structure of a 3D package.

Referring to FIG. 4B, the top face of the second interposer 72 of the basic structure is added with a third chip 731 to form a first extended structure 73, wherein the top face of the second interposer 72 is acts as an interposer, and on the interposer, a third chip 731 is wire bonded electrically.

Referring to FIG. 4C, the first extended structure 73 of FIG. 4B is provided with a third interposer 740, and the bottom side of the interposer is connected with a forth chip 741. After that a second flexible circuit board 76 on the second interposer 72 employs an anisotropic conductive film/paste 735, 745 method to connect the second flexible circuit board 76 to the inner side of the third interposer 740 to form a second extended structure 74.

The above second extended structure 74 is not restricted to two-layered basic structure. Under available space, multiple-layered structure can be formed. The first extended structure 73 can also be implemented on the second extended structure

It will be understood that each of the elements described above, or two or more together may also find a useful application in other types of methods differing from the type described above.

While certain novel features of this invention have been shown and described and are pointed out in the annexed claim, it is not intended to be limited to the details above, since it will be understood that various omissions, modifications, substitutions and changes in the forms and details of the device illustrated and in its operation can be made by those skilled in the art without departing in any way from the spirit of the present invention.

I claim:

1. A structure of a combination-type 3-D stack IC package comprising
(a) a first interposer mounted electrically with a first chip;
(b) a second interposer having electrically mounted with a second chip at the bottom face of the interposer; and
(c) a flexible circuit board at the inner side of the first interposer and the second interposer being connected using anisotropic conductive film/paste to form a basic structure.

2. The structure of claim 1, wherein the bottom face of the first interposer is mounted with solder ball.

3. The structure of claim 2, wherein the top face of the second interposer is an interposer having connected to a chip.

4. The structure of claim 2, wherein the top face of the second interposer is an interposer having connected to a chip, and the top face of the interposer is provided with a third interposer and a third chip is connected to the interposer and a flexible circuit board is used to anisotropic conductive film/paste connect the second interposer to the inner side of the third interposer to form a layer of stacked extended structure.

5. The method of a combination-type 3-D stack IC package of claim 3, wherein the connection between the chip and the interposer is formed by flip chip.

6. The method of a combination-type 3-D stack IC package of claim 3, wherein the connection between the chip and the interposer is formed by wire bonding.
